(19) United States
(12) Patent Application Publication
(10) Pub. No.: US 2003/0006785 A1
(43) Pub. Date: Jan. 9, 2003

(54) Temperature recording device

(76) Inventor: Manfred Reiss, Ingolstadt (DE)

Correspondence Address: MERCHANT & GOULD PC, P.O. BOX 2903, MINNEAPOLIS, MN, 55402-0903, US

(21) Appl. No.: 10/009,137

(22) PCT Filed: Mar. 9, 2001
(86) PCT No.: PCT/EP01/02657

(30) Foreign Application Priority Data
Mar. 10, 2000 (DE) 100 11 662.0

(51) Int. Cl. G01R 27/08

(52) U.S. Cl. 324/703

(57) ABSTRACT

A temperature detection device is provided for an electronic circuit, in particular for a HF tuner. The temperature detection device comprises a temperature detector, an analog-to-digital converter and a standardized serial bus. At its output the temperature detector makes available a temperature-dependent voltage that is a predetermined function of the temperature. The temperature-dependent voltage is applied to the input of the analog-to-digital converter. On its output side, the analog-to-digital converter is coupled to the standardized serial bus.

### DESCRIPTION

The invention relates to a temperature detection device for an electronic circuit.

Nearly all the characteristic properties of electronic components depend on the temperature. Especially in the case of semiconductor components, most of the electrical parameters are temperature-dependent. As a consequence, the ambient temperature in places where electrical circuits are situated is of substantial significance with respect to the circuits' characteristics and parameters. The temperature resulting from operation of the circuits themselves also plays a role. For example, the gain and frequency response of an amplifier are temperature-dependent. It is desirable for information about the temperature to be available in order to determine the temperature dependence of electrical quantities and/or, where appropriate, to be able to compensate thermally induced deviations of electrical quantities.

The objective of the invention is to make available a temperature detection device for an electronic circuit that provides temperature information that can be further processed, while keeping the complexity and cost of construction of the device within tolerable limits.

This objective is achieved by the device that is the subject matter of claim 1.

In accordance with the invention a temperature detection device for an electronic circuit is provided that comprises the following:

a temperature detector that at its output makes available a voltage that is a predetermined function of the temperature;

an analog-to-digital converter, to the input of which the temperature-dependent voltage is applied;

a standardized serial bus to which the analog-to-digital converter is coupled.

The temperature detection device in accordance with the invention can be constructed with little effort, at low cost. The temperature detector can be made of active and/or passive electronic components. The temperature behavior of most commercially available components is known, so that for the temperature detector the functional relationship between temperature and voltage is fixed. As analog-to-digital converter an integrated circuit is preferably used. In many cases an analog-to-digital converter is already present in the electronic circuit and can be used for the temperature detection device. By way of the standardized serial bus the temperature signal can be sent as a standardized digital signal to other electronic components for further processing.

Preferably it is provided that the temperature detector consists of a voltage divider comprising a resistance element and a temperature sensor. This allows an output voltage that is a predetermined function of the temperature to be generated in a simple manner.

In an especially economical embodiment it is provided that the temperature sensor is a temperature-dependent resistor. For this purpose both a barretter (PTC resistor) and a high-temperature thermistor (NTC) can be used. Instead of the temperature-dependent resistor it is possible to use other electronic components with known temperature behavior. For example, a transistor with known temperature dependence of its family of characteristics can also be used.

It can further be provided that the standardized serial bus is an I²C bus or a 3-wire bus. By this means the device can be made compatible with other components in the electronic circuit. The temperature information is provided as a standardized serial digital signal and can be further processed by other componentry. Furthermore, the temperature information can also be sent to external circuits by way of the bus.

Preferably the temperature detection device is provided for a HF tuner. In the case of a tuner, the influence of temperature is especially important. A tuner must enable the reception frequency in particular to be adjusted very precisely. Thermally induced fluctuations can impair the adjustment precision of the tuner directly or indirectly. If the temperature detection device makes available information as to the actual momentary temperature, undesired thermally induced deviations can be corrected. This process can occur both within the tuner and externally in a peripheral circuit, for example in a microprocessor.

In one economical embodiment it can be provided that the analog-to-digital converter is part of an integrated PLL circuit. In the tuners used today, a PLL circuit is ordinarily already present, usually as an integrated circuit. In many cases the integrated PLL circuit comprises an analog-to-digital converter that can be used for the temperature detection device. Similarly, in most tuners a standardized bus is present, which can likewise be used for the temperature detection device. In the most favorable case the temperature detection device in accordance with the invention can be implemented by adding only one part, namely the temperature detector.

In the following, a preferred embodiment of a temperature detection device in accordance with the invention is explained in detail with reference to the single drawing.

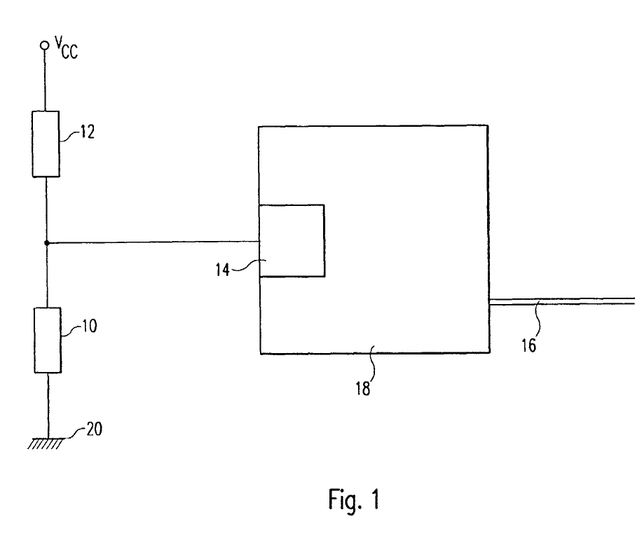

FIGURE 1 shows a circuit diagram of a temperature detection device constructed in accordance with the invention, incorporated into a HF tuner. The preferred embodiment comprises a temperature sensor 10 and a resistance element 12. The temperature sensor 10 and the resistance element 12 are connected in series between a voltage source V_{cc} and a ground site 20, forming a voltage divider. The point where the temperature sensor 10 is coupled to the resistance element 12 is at a temperature-dependent voltage Vₜ. Because the electrical and thermal properties of the temperature sensor 10 and the resistance element 12 are known, the relationship between the voltage Vₜ and the temperature is also known. As the temperature sensor 10, in particular a barretter (PTC resistor) or a high-temperature thermistor (NTC) can be used. Transistors and similar elements with known temperature behavior can in principle also be used as the temperature sensor 10. The temperature sensor 10 and the resistance element 12, connected in series between a voltage source V_{cc} and ground, together form a temperature detector. The coupling point between temperature sensor 10 and resistance element 12 forms an output of the temperature detector.

By way of its output, the temperature detector is coupled to an analog-to-digital converter 14. The analog-to-digital converter 14 transforms the temperature-dependent voltage Vₜ into a standardized digital data element. The analog-to-digital converter 14 is part of an integrated PLL circuit 18. This integrated PLL circuit 18 is in turn a component of a HF tuner. The HF tuner also comprises a standardized serial bus 16. The standardized serial bus 16 preferably has the form of an I²C bus or 3-wire bus. The serial bus 16 is coupled to the integrated PLL circuit 18. Within the integrated PLL circuit 18, the serial bus 16 is coupled to the output of the analog-to-digital converter 14. This arrangement allows the serial bus 16 to deliver a compatible digital signal from the analog-to-digital converter 14, which contains information about the sensed temperature and can be further processed by other componentry.

Circuits that can be used as the integrated PLL circuit 18 include, for example, the commercially available circuits TSA 5522 and TSA 5523, both of which comprise an internal analog-to-digital converter. Furthermore, both of these integrated components can be controlled by way of an I²C bus.

By means of the temperature detection device in accordance with the invention the actual momentary temperature can be expressed as a standardized digital signal and thus sent to other components within the tuner and also to external devices. For example, a microprocessor and a semiconductor memory unit, in particular an electrically erasable semiconductor memory (EEPROM), can be connected to the serial bus 16. This enables the temperature-dependence of electrical parameters of the tuner to be measured and stored in the semiconductor memory. With the device in accordance with the invention it is possible to detect the momentary temperature during operation and, where required, to respond to undesired thermally-induced deviations. In taking such compensatory measures, the stored calibration curves can be used as a basis for calculation.

The temperature detection device in accordance with the invention is in principle suitable for any electronic circuit. The temperature detection device is especially advantageous for circuits that already comprise an analog-to-digital converter and/or a serial bus. In the latter case, the temperature detection device can be implemented very simply and hence at low cost.

### List of Reference Numerals

Temperature sensor

Resistance element

Analog-to-digital converter

Serial bus

Integrated PLL circuit

Ground

1. Temperature detection device for an electronic circuit, comprising the following:
a temperature detector, which at its output makes available a voltage (Vₜ) that is a predetermined function of the temperature;
an analog-to-digital converter (14), to the input of which the temperature-dependent voltage (Vₜ) is applied; and
a standardized serial bus (16), to which the output of the analog-to-digital converter (14) is coupled.

2. Temperature detection device according to claim 1, characterized in that the temperature detector consists of a voltage divider comprising a temperature sensor (10) and a resistance element (12).

3. Temperature detection device according to claim 2, characterized in that the temperature sensor (10) is a barretter (PCT resistor) or a high-temperature thermistor (NTC).

4. Temperature detection device according to one of the claims 1 to 3, characterized in that the standardized serial bus is an I²C bus or a 3-wire bus.

5. Temperature detection device according to one of the claims 1 to 4, characterized in that the temperature detection device is provided for a HF tuner.

6. Temperature detection device according to claim 5, characterized in that the analog-to-digital converter (14) is part of an integrated PLL circuit of the HF tuner.
